(19) United States
(12) Patent Application Publication
(10) Pub. No.: US 2025/0365858 A1
(43) Pub. Date: Nov. 27, 2025

(54) WIRING BODY AND DISPLAY DEVICE

(71) Applicant: TDK Corporation, Tokyo (JP)

(72) Inventors: Yuusuke IKEMURA, Tokyo (JP); Yasumasa HARIHARA, Tokyo (JP); Tomoyuki GOI, Tokyo (JP); Hiroshi SHINGAI, Tokyo (JP)

(73) Assignee: TDK Corporation, Tokyo (JP)

(21) Appl. No.: 19/294,332

(22) Filed: Aug. 8, 2025

Related U.S. Application Data
(63) Continuation of application No. PCT/JP2024/005321, filed on Feb. 15, 2024.

(30) Foreign Application Priority Data
Feb. 17, 2023 (JP) 2023-023509

(51) Int. Cl. H05K 1/02

(52) U.S. Cl. CPC H05K 1/0296; H05K 2201/09036; H05K 2201/10128

(57) ABSTRACT

A wiring body including a substrate, and a conductor pattern provided on the substrate and including an electroconductive line, the electroconductive line extending on the substrate in an extending direction, in which, in a cross-sectional view of the electroconductive line taken along a direction orthogonal to the extending direction, a width of the electroconductive line increases toward one side away from the substrate in a height direction, and a curved surface curving so as to protrude to the one side in the height direction is formed on a surface of the electroconductive line on a side opposite to the substrate.

### CROSS REFERENCE TO RELATED APPLICATIONS

This application is a continuation application of PCT Application No. PCT/JP2024/005321, filed on Feb. 15, 2024, which claims the benefit of priority from Japanese Patent Application No. 2023-023509, filed on Feb. 17, 2023. The entire contents of the above listed PCT and priority applications are incorporated herein by reference.

### TECHNICAL FIELD

The present disclosure relates to a wiring body and a display device.

### BACKGROUND

A wiring body has been conventionally known which includes a substrate, a mesh-like conductor pattern provided on the substrate, and a resin layer provided on the substrate (for example, Japanese Unexamined Patent Publication No. 2021-78063). A trench is formed in the resin layer, and an electroconductive line of the conductor pattern is formed in the trench.

### SUMMARY

A wiring body according to an aspect of the present disclosure including a substrate, and a conductor pattern provided on the substrate and including an electroconductive line, the electroconductive line extending on the substrate in an extending direction, in which, in a cross-sectional view of the electroconductive line taken along a direction orthogonal to the extending direction, a width of the electroconductive line increases toward one side away from the substrate in a height direction, and a curved surface curving so as to protrude to the one side in the height direction is formed on a surface of the electroconductive line on a side opposite to the substrate.

A display device according to an aspect of the present disclosure includes the wiring body.

### BRIEF DESCRIPTION OF THE DRAWINGS

FIG. 1 is a plan view illustrating an electroconductive film including a wiring body according to an embodiment.

FIG. 2 is a cross-sectional view taken along the line II-II in FIG. 1.

FIG. 3 is a cross-sectional view illustrating an electroconductive film according to a modification.

FIG. 4 is a cross-sectional view illustrating a display device according to an embodiment.

FIG. 5 is a plan view of an antenna including a wiring body.

FIG. 6 is an enlarged cross-sectional view taken along the line VI-VI in FIG. 5.

FIG. 7 is an enlarged cross-sectional view of a first electroconductive line near a curved surface.

FIG. 8 is an enlarged cross-sectional view illustrating a wiring body according to a modification.

FIG. 9 is an enlarged cross-sectional view illustrating a wiring body according to a modification.

### DETAILED DESCRIPTION

Here, in the above-described wiring body, in some cases, the volume of the electroconductive line is increased to lower the electric resistance of the conductor pattern in order to reduce the sheet resistance. However, increasing the volume of the electroconductive line causes a problem that the visibility of the conductor pattern in the wiring body increases.

In view of the above, an object of the present disclosure is to provide a wiring body capable of reducing the sheet resistance while preventing an increase in visibility of a conductor pattern, and a display device.

According to an aspect of the present disclosure, it is possible to provide a wiring body capable of reducing the sheet resistance while preventing an increase in visibility of a conductor pattern, and a display device.

Hereinafter, some embodiments of the present disclosure will be described in detail. However, the present disclosure is not limited to the following embodiments.

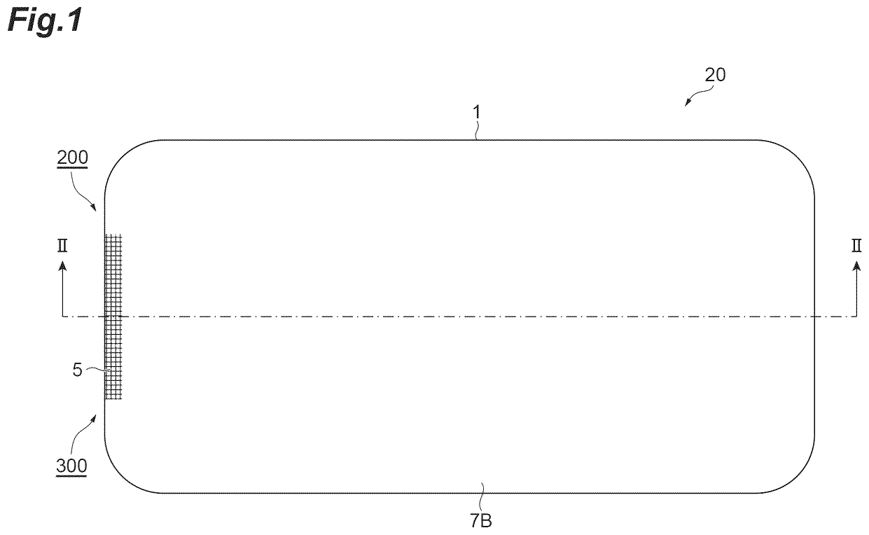

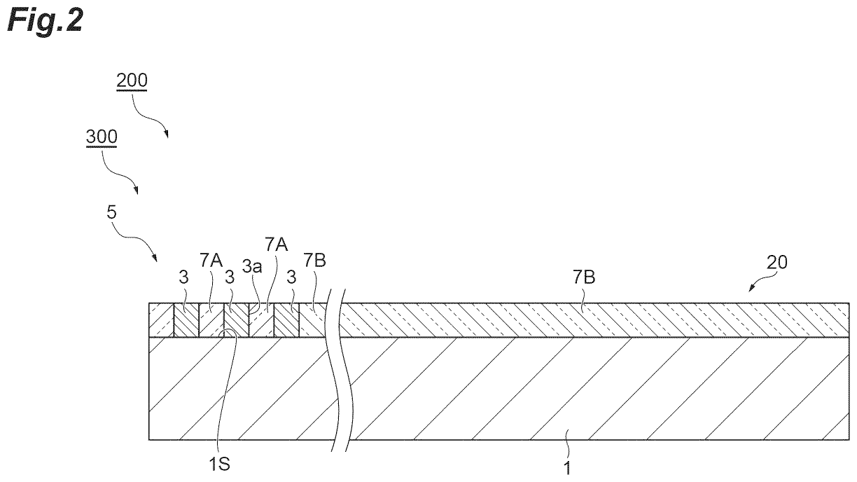

FIG. 1 is a plan view illustrating an electroconductive film including a wiring body 200 according to an embodiment of the present disclosure, and FIG. 2 is a cross-sectional view taken along the line II-II in FIG. 1. An electroconductive film 20 includes an antenna 300, and the antenna 300 includes the wiring body 200. An electroconductive film 20 illustrated in FIGS. 1 and 2 includes a film-like light transmissive substrate 1 (substrate), an electroconductive layer 5 provided on one main surface 1S of the light transmissive substrate 1, and a light transmissive resin layer 7B provided on that one main surface 1S of the light transmissive substrate 1. The electroconductive layer 5 includes a conductor portion 3 that includes a part having a pattern extending in a direction along the main surface 1S of the light transmissive substrate 1 and including a plurality of openings 3a, and an insulating resin portion 7A filling the openings 3a of the conductor portion 3. In FIG. 2, the electroconductive layer 5 is illustrated in a deformed manner, and the width of the conductor portion 3 is illustrated in an emphasized manner. The thickness of each layer is also illustrated in a deformed manner. Details of the thickness of each layer will be described later. In the example illustrated in FIG. 1, the electroconductive layer 5 is formed near one short side of the electroconductive film 20, but the position where the electroconductive layer 5 is formed is not particularly limited, and the electroconductive layer 5 may be formed near a long side.

The light transmissive substrate 1 has optical transparency to an extent required when the electroconductive film 20 is incorporated in a display device. Specifically, the total light transmittance of the light transmissive substrate 1 may be 90 to 100%. The light transmissive substrate 1 may have a haze of 0 to 5%.

The light transmissive substrate 1 may be, for example, a transparent resin film, and examples thereof include a film of polyethylene terephthalate (PET), polycarbonate (PC), polyethylene naphthalate (PEN), cycloolefin polymer (COP), or polyimide (PI). Alternatively, the light transmissive substrate 1 may be a glass substrate.

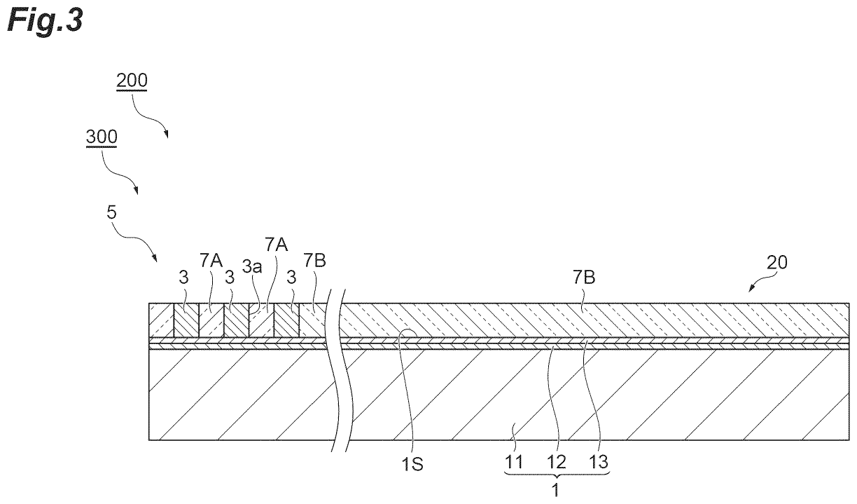

For example, as illustrated in FIG. 3, the light transmissive substrate 1 may be a laminate including a light transmissive support film 11, and an intermediate resin layer 12 and an underlying layer 13 sequentially provided on the support film 11. The support film 11 can be the transparent resin film. The underlying layer 13 is a layer provided 20) in order to form the conductor portion 3 by electroless plating or the like. In a case where the conductor portion 3 is formed by another method, the underlying layer 13 is not necessarily provided. It is not essential that the intermediate resin layer 12 is provided between the support film 11 and the underlying layer 13.

The thickness of the light transmissive substrate 1 or the support film 11 constituting the same may be 10 μm or more, 20 μm or more, or 35 μm or more, and may be 500 μm or less, 200 μm or less, or 100 μm or less.

Providing the intermediate resin layer 12 can improve adhesion between the support film 11 and the underlying layer 13. In a case where the underlying layer 13 is not provided, the intermediate resin layer 12 is provided between the support film 11 and the light transmissive resin layer 7B, so that adhesion between the support film 11 and the light transmissive resin layer 7B can be improved.

The intermediate resin layer 12 may be a layer containing a resin and an inorganic filler. Examples of the resin constituting the intermediate resin layer 12 include an acrylic resin. Examples of the inorganic filler include silica.

The thickness of the intermediate resin layer 12 may be, for example, 5 nm or more, 100 nm or more, or 200 nm or more, and may be 10 μm or less, 5 μm or less, or 2 μm or less.

The underlying layer 13 may be a layer containing a catalyst and a resin. The resin may be a cured product of a curable resin composition. Examples of a curable resin contained in the curable resin composition include an acrylic resin, an amino resin, a cyanate resin, an isocyanate resin, a polyimide resin, an epoxy resin, an oxetane resin, a polyester, an allyl resin, a phenolic resin, a benzoxazine resin, a xylene resin, a ketone resin, a furan resin, a COPNA resin, a silicon resin, a dicyclopentadiene resin, a benzocyclobutene resin, an episulfide resin, a thiol-ene resin, a polyazomethine resin, a polyvinyl benzyl ether compound, acenaphthylene, and an ultraviolet curable resin containing a functional group that causes a polymerization reaction with ultraviolet rays such as an unsaturated double bond, a cyclic ether, and a vinyl ether.

The catalyst contained in the underlying layer 13 may be an electroless plating catalyst. The electroless plating catalyst may be a metal selected from Pd, Cu, Ni, Co, Au, Ag, Pd, Rh, Pt, In, and Sn, or may be Pd. The catalyst may be one kind alone or a combination of two or more kinds. Usually, the catalyst is dispersed in the resin as catalyst particles.

The content of the catalyst in the underlying layer 13 may be 3 mass % or more, 4 mass % or more, or 5 mass % or more, and may be 50 mass % or less, 40 mass % or less, or 25 mass % or less with respect to the total amount of the underlying layer 13.

The thickness of the underlying layer 13 may be 10 nm or more, 20 nm or more, or 30 nm or more, and may be 500 nm or less, 300 nm or less, or 150 nm or less.

The light transmissive substrate 1 may further include a protective layer provided on a main surface of the support film 11 opposite to the light transmissive resin layer 7B and the conductor portion 3. Providing the protective layer prevents the support film 11 from being scratched. The protective layer can be a layer similar to the intermediate resin layer 12. The thickness of the protective layer may be 5 nm or more, 50 nm or more, or 500 nm or more, and may be 10 μm or less, 5 μm or less, or 2 μm or less.

The conductor portion 3 constituting the electroconductive layer 5 includes a part having a pattern including the openings 3a. The pattern including the openings 3a is a mesh-like pattern that is formed by a plurality of linear portions intersecting each other and includes the plurality of openings 3a regularly arranged. The conductor portion 3 having the mesh-like pattern can favorably function as, for example, a radiation conductor and a feed line of the antenna 300. The conductor portion 3 includes a planar pattern having no openings 3a. The conductor portion 3 having the planar pattern functions as a terminal and a ground pad portion described later. The configuration of the pattern of the conductor portion 3 in the electroconductive layer 5 will be detailed later.

The conductor portion 3 may contain metal. The conductor portion 3 may contain at least one metal selected from copper, nickel, cobalt, palladium, silver, gold, platinum, and tin, or may contain copper. The conductor portion 3 may be metal plating formed by a plating method. The conductor portion 3 may further contain a nonmetallic element such as phosphorus within a range in which appropriate conductivity is maintained.

The conductor portion 3 may be a laminate including a plurality of layers. In addition, the conductor portion 3 may have a blackened layer as a surface layer portion on a side opposite to the light transmissive substrate 1. The blackened layer can contribute to improvement in visibility of a display device in which the electroconductive film is incorporated.

The insulating resin portion 7A is formed of a light transmissive resin and is provided so as to fill the openings 3a of the conductor portion 3, and the insulating resin portion 7A and the conductor portion 3 usually form a flat surface.

The light transmissive resin layer 7B is formed of a light transmissive resin. The total light transmittance of the light transmissive resin layer 7B may be 90 to 100%. The light transmissive resin layer 7B may have a haze of 0 to 5%.

The difference between the light transmissive substrate 1 (or the refractive index of the support film constituting the light transmissive substrate 1) and the refractive index of the light transmissive resin layer 7B may be 0.1 or less. As a result, good visibility of a display image is more easily achieved. The refractive index (nd 25) of the light transmissive resin layer 7B may be, for example, 1.0 or more, and may be 1.7 or less, 1.6 or less, or 1.5 or less. The refractive index can be measured by a spectroscopic ellipsometer. In terms of uniformity of the optical path length, the conductor portion 3, the insulating resin portion 7A, and the light transmissive resin layer 7B may have substantially the same thickness.

The resin forming the insulating resin portion 7A and the light transmissive resin layer 7B may be a cured product of a curable resin composition (photocurable resin composition or thermosetting resin composition). The curable resin composition forming the insulating resin portion 7A and/or the light transmissive resin layer 7B includes a curable resin, and examples thereof include an acrylic resin, an amino resin, a cyanate resin, an isocyanate resin, a polyimide resin, an epoxy resin, an oxetane resin, a polyester, an allyl resin, a phenolic resin, a benzoxazine resin, a xylene resin, a ketone resin, a furan resin, a COPNA resin, a silicon resin, a dicyclopentadiene resin, a benzocyclobutene resin, an episulfide resin, a thiol-ene resin, a polyazomethine resin, a polyvinyl benzyl ether compound, acenaphthylene, and an ultraviolet curable resin containing a functional group that causes a polymerization reaction with ultraviolet rays such as an unsaturated double bond, a cyclic ether, and a vinyl ether.

The resin forming the insulating resin portion 7A and the resin forming the light transmissive resin layer 7B may be the same. Since the insulating resin portion 7A and the light transmissive resin layer 7B formed of the same resin have the same refractive index, the uniformity of the optical path length transmitted through the electroconductive film 20 can be further improved. In a case where the resin forming the insulating resin portion 7A and the resin forming the light transmissive resin layer 7B are the same, for example, the insulating resin portion 7A and the light transmissive resin layer 7B can be easily and collectively formed by forming a pattern from one curable resin layer by an imprinting method or the like.

The electroconductive film 20 can be manufactured, for example, by a method including pattern formation by the imprinting method. An example of a method for manufacturing the electroconductive film 20 includes: preparing the light transmissive substrate 1 including the support film, the intermediate resin layer, and the underlying layer containing the catalyst, the intermediate resin layer, and the underlying layer being provided on one main surface of the support film; forming the curable resin layer on the main surface 1S on the underlying layer side of the light transmissive substrate 1; forming a trench in which the underlying layer is exposed by an imprinting method using a mold having a convex portion; and forming the conductor portion 3 filling the trench by an electroless plating method in which metal plating is grown from the underlying layer. The curable resin layer is cured in a state where the mold is pushed into the curable resin layer to thereby form collectively the insulating resin portion 7A having a pattern including an opening with an inverted shape of the convex portion of the mold, and the light transmissive resin layer 7B. The method for forming the insulating resin portion 7A having the pattern including the opening is not limited to the imprinting method, and any method such as photolithography can be applied.

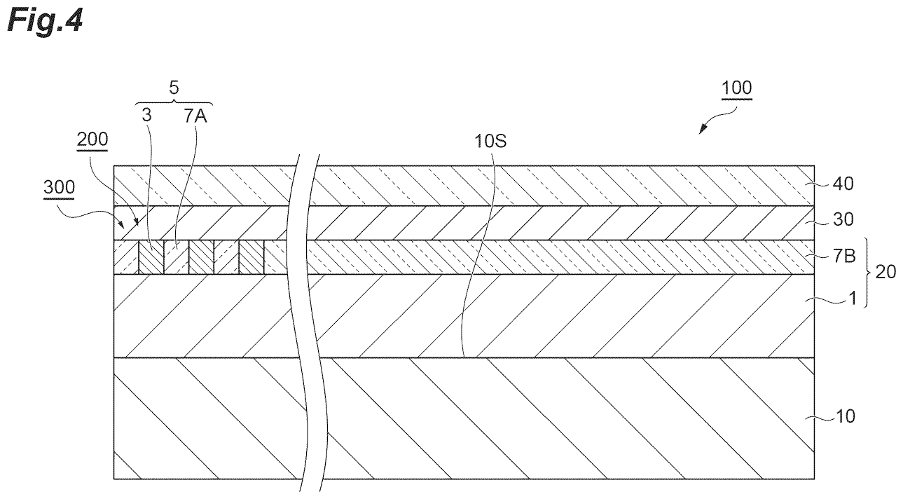

The electroconductive film described above as an example can be incorporated into a display device as, for example, a planar transparent antenna. The display device may be, for example, a liquid crystal display device or an organic EL display device. FIG. 4 is a cross-sectional view illustrating an embodiment of a display device in which 20) an electroconductive film is incorporated. A display device 100 illustrated in FIG. 4 includes an image display unit 10 having an image display region 10S, an electroconductive film 20, a polarizing plate 30, and a cover glass 40. The electroconductive film 20, the polarizing plate 30, and the cover glass 40 are laminated, in this order from the image 25 display unit 10 side, on the image display region 10S side of the image display unit 10. The configuration of the display device is not limited to the form of FIG. 4, and can be appropriately changed as necessary. For example, the polarizing plate 30 may be provided between the image display unit 10 and the electroconductive film 20. The image display unit 10 may be, for example, a liquid crystal display unit. As the polarizing plate 30 and the cover glass 40, those commonly used in a display device can be used. The polarizing plate 30 and the cover glass 40 are not necessarily provided. Light for image display emitted from the image display region 10S of the image display unit 10 passes through a path having a highly uniform optical path length including the electroconductive film 20. This makes it possible to display an image with high uniformity and favorable quality with suppressed moire.

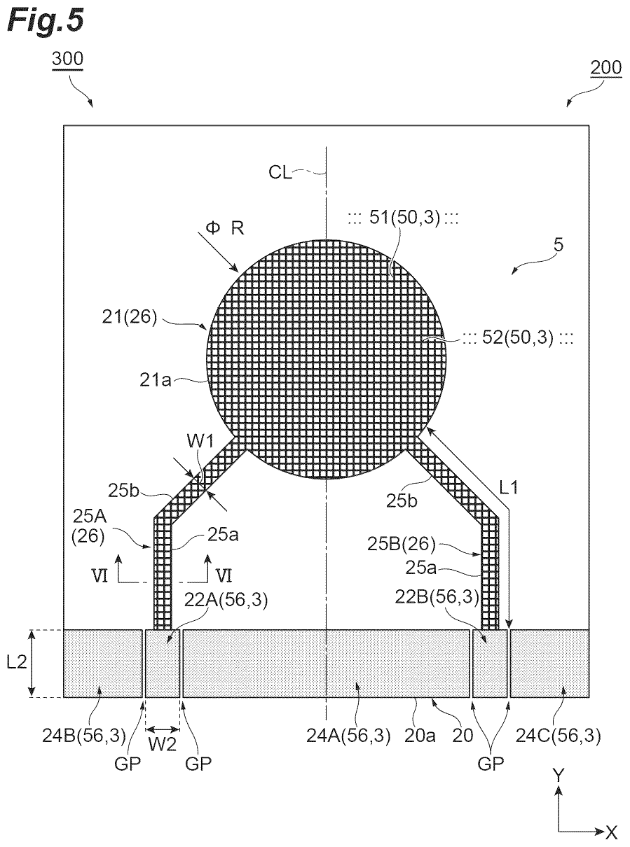

Next, a configuration of the antenna 300 including the wiring body 200 according to the embodiment of the present disclosure will be described in detail with reference to FIG. 5. The antenna 300 includes the electroconductive layer 5 described above. FIG. 5 is a plan view of the antenna 300. FIG. 5 is an enlarged view of a part of the antenna 300 including the wiring body 200. In the following description, it is assumed that XY coordinates are set with respect to a plane parallel to the main surface 1S. The Y-axis direction is a direction along the main surface 1S. In the example illustrated in FIG. 1, the Y-axis direction corresponds to a direction orthogonal to a side portion 20a of the electroconductive film 20. The center side of the electroconductive film 20 is defined as a positive side in the Y-axis direction, and the outer peripheral side of the electroconductive film 20 is defined as a negative side in the Y-axis direction. The X-axis direction is a direction orthogonal to the Y-axis direction along the main surface 1S. In the example illustrated in FIG. 1, the X-axis direction corresponds to a direction in which the side portion 20a of the electroconductive film 20 extends. One side in which the side portion 20a of the electroconductive film 20 extends is defined as a positive side in the X-axis direction, and the other side is defined as a negative side in the X-axis direction. In the example illustrated in FIG. 5, the antenna 300 is illustrated as a single antenna element, but the present disclosure is not limited thereto, and a plurality of antennas 300 may be arranged in the X-axis direction to form an array antenna.

The electroconductive layer 5 of the antenna 300 includes an electrode 26 including a radiation electrode 21 and feed lines 25A and 25B, terminals 22A and 22B, and ground pad portions 24A, 24B, and 24C. The antenna 300 has a linear symmetrical configuration with respect to a center line CL parallel to the Y-axis direction.

The radiation electrode 21 is a region that radiates a signal as the antenna 300. The radiation electrode 21 has a circular shape. The center of the radiation electrode 21 is located on the center line CL. The radiation electrode 21 is disposed at a position spaced apart from the side portion 20a of the electroconductive film 20 toward the positive side in the Y-axis direction. The radiation electrode 21 has a dimension of a diameter R.

The feed lines 25A and 25B are lines for feeding power to the radiation electrode 21. That is, the antenna 300 functions as a dual-polarized antenna. For example, a diagonally polarized signal in a direction in which an inclined portion 25b of the feed line 25A extends can be fed via the feed line 25A, and a diagonally polarized signal in a direction in which an inclined portion 25b of the feed line 25B extends can be fed via the feed line 25B. The feed lines 25A and 25B each have a vertical portion 25a extending perpendicular to the side portion 20a of the electroconductive film 20 and an inclined portion 25b inclined with respect to the Y-axis direction. The vertical portion 25a of the feed line 25A extends toward the positive side in the Y-axis direction from the terminal 22A formed on the side portion 20a side of the electroconductive film 20. The vertical portion 25a of the feed line 25A extends in parallel with the center line CL (that is, the Y-axis direction) at a position spaced apart from the center line CL toward the negative side in the X-axis direction.

The inclined portion 25b of the feed line 25A is inclined, from an end part of the vertical portion 25a on the positive side in the Y-axis direction, so as to approach the center line CL side (that is, the positive side in the X-axis direction) as the inclined portion 25b extends toward the positive side in the Y-axis direction. An end part of the inclined portion 25b on the positive side at the Y-axis direction is connected to an outer peripheral edge 21a of the radiation electrode 21. The feed line 25A has a constant width dimension W1 at the vertical portion 25a and the inclined portion 25b. In addition, the feed line 25A has a line length L1 that is the total dimension of the length dimension of the vertical portion 25a and the length dimension of the inclined portion 25b. Here, the width dimension W1 is a dimension in a direction orthogonal to the extending direction of the vertical portion 25a and the inclined portion 25b in the in-plane direction of the planar antenna 300, and the line length L1 is a dimension along the extending direction of the vertical portion 25a and the inclined portion 25b in the in-plane direction of the planar antenna 300.

Note that, in the example illustrated in FIG. 5, the vertical portion 25a of the feed line 25A is disposed at a position spaced apart from an end part of the radiation electrode 21 on the negative side in the X-axis direction toward the negative side in the X-axis direction. In addition, the end part of the vertical portion 25a of the feed line 25A on the positive side in the Y-axis direction (that is, the part connected to the inclined portion 25b) is disposed at a position spaced apart from an end part of the radiation electrode 21 on the negative side in the Y-axis direction toward the negative side in the Y-axis direction. However, the arrangement and shapes of the vertical portion 25a and the inclined portion 25b are not particularly limited. The feed line 25B has a structure that is linearly symmetrical to the feed line 25A with respect to the center line CL. In the present embodiment, the inclined portion 25b of the feed line 25A and the inclined portion 25b of the feed line 25B are connected to the outer peripheral edge 21a of the radiation electrode 21 such that a virtual line obtained by extending the inclined portion 25b of the feed line 25A and a virtual line obtained by extending the inclined portion 25b of the feed line 25B are orthogonal to each other. In other words, the angle formed by the virtual line obtained by extending the inclined portion 25b of the feed line 25A and the virtual line obtained by extending the inclined portion 25b of the feed line 25B is 90 degrees.

The terminals 22A and 22B are terminals connected to the feed lines 25A and 25B, respectively. The terminals 22A and 22B are connected to an external input/output terminal to supply power to the radiation electrode 21 via the feed lines 25A and 25B. The terminals 22A and 22B are disposed near the side portion 20a of the electroconductive film 20. The terminals 22A and 22B extend from end parts of the vertical portions 25a of the feed lines 25A and 25B on the negative side in the Y-axis direction to the side portion 20a toward the negative side in the Y-axis direction. The terminals 22A and 22B each extend in the Y-axis direction with a constant width dimension W2. The terminals 22A and 22B each extend in the Y-axis direction with a length dimension L2. Here, the width dimension W2 is a dimension in a direction orthogonal to the extending direction of the terminals 22A and 22B in the in-plane direction of the planar antenna 300. The length dimension L2 is a dimension along the extending direction of the terminals 22A and 22B in the in-plane direction of the planar antenna 300.

The ground pad portions 24A, 24B, and 24C are electrically grounded regions. The ground pad portions 24A, 24B, and 24C are connected to a ground terminal (not illustrated). The ground pad portions 24A, 24B, and 24C are arranged with a gap GP with respect to the terminals 22A and 22B to thereby be insulated from the terminals 20) 22A and 22B. The ground pad portion 24A is formed to extend in the X-axis direction along the side portion 20a in a region between the terminals 22A and 22B. The ground pad portion 24B is formed to extend in the X-axis direction along the side portion 20a in a region on the negative side in the X-axis direction of the terminal 22A. The ground 25 pad portion 24C is formed to extend in the X-axis direction along the side portion 20a in a region on the positive side in the X-axis direction of the terminal 22B. The ground pad portions 24A, 24B, and 24C have a constant width in the Y-axis direction and extend in a band shape in the X-axis direction. The width of each of the ground pad portions 24A, 24B, and 24C is the same as the length dimension L2 of each of the terminals 22A and 22B.

As described above, the terminal 22A, which is a signal line, has a structure sandwiched between the ground pad portions 24A and 24B from both sides the terminal 22A in the X-axis direction. The terminal 22B, which is a signal line, has a structure sandwiched between the ground pad portions 24A and 24C from both sides of the terminal 22B in the X-axis direction. The terminals 22A and 22B are thus coplanar lines.

As illustrated in FIG. 5, the antenna 300 includes a mesh-like conductor pattern 50 as the conductor portion 3. Among the constituent elements of the antenna 300, the radiation electrode 21 and the feed lines 25A and 25B (electrodes) each have the mesh-like conductor pattern 50. The mesh-like conductor pattern 50 includes a plurality of first electroconductive lines 51 and a plurality of second electroconductive lines 52. The first electroconductive line 51 is the linear conductor portion 3 extending parallel to the Y-axis direction. The plurality of first electroconductive lines 51 is arranged to be spaced apart from each other in the X-axis direction. The plurality of first electroconductive lines 51 is arranged to be spaced apart at a constant pitch. The second electroconductive line 52 is the linear conductor portion 3 extending parallel to the X-axis direction. The plurality of second electroconductive lines 52 is arranged to be spaced apart from each other in the Y-axis direction. The plurality of second electroconductive lines 52 is arranged to be spaced apart at a constant pitch. The thickness of the electroconductive lines 51 and 52 is not particularly limited, and may be set to, for example, 1 to 3 μm. The pitch of the electroconductive lines 51 and 52 is not particularly limited, and may be set to, for example, 100 to 300 μm. The first electroconductive line 51 does not need to be parallel to the Y-axis direction as long as the first electroconductive line 51 extends in the Y-axis direction, and the second electroconductive line 52 does not need to be parallel to the X-axis direction as long as the second electroconductive line 52 extends in the X-axis direction.

In the present embodiment, the radiation electrode 21 and the feed lines 25A and 25B have end electroconductive lines constituting the outer peripheral edges. The radiation electrode 21 has a circular shape formed by the end electroconductive line. Note that the radiation electrode 21 having a circular shape is not limited to have a strictly perfect circular shape, and includes variations caused by manufacturing errors and the like. In addition, the end electroconductive line constituting the outer peripheral edge of the radiation electrode 21 is not limited to a curved line only, and may partially include a straight line and a wavy line portion. Further, it is not always necessary that the radiation electrode 21 and the feed lines 25A and 25B include the end electroconductive lines. In this case, it is only required that the shape formed by connecting the ends of the first electroconductive lines 51 or the second electroconductive lines 52 included in the mesh-like conductor pattern 50 is a circular shape.

The terminal 22 has a second conductor layer 56 extending in a planar shape over substantially the entire region of the terminal 22. Note that the term “terminal 22” is used to refer to both the terminal 22A and the terminal 22B without distinction. In FIG. 5, the second conductor layer 56 is formed over the entire region of the terminal 22, but the area of the second conductor layer 56 is not particularly limited. For example, the area of the second conductor layer 56 may be 95% or more of the area of the entire terminal 22. Note that the ground pad portions 24A, 24B, and 24C also include the second conductor layer 56. However, the ground pad portions 24A, 24B, and 24C may have a configuration including the mesh-like conductor pattern 50.

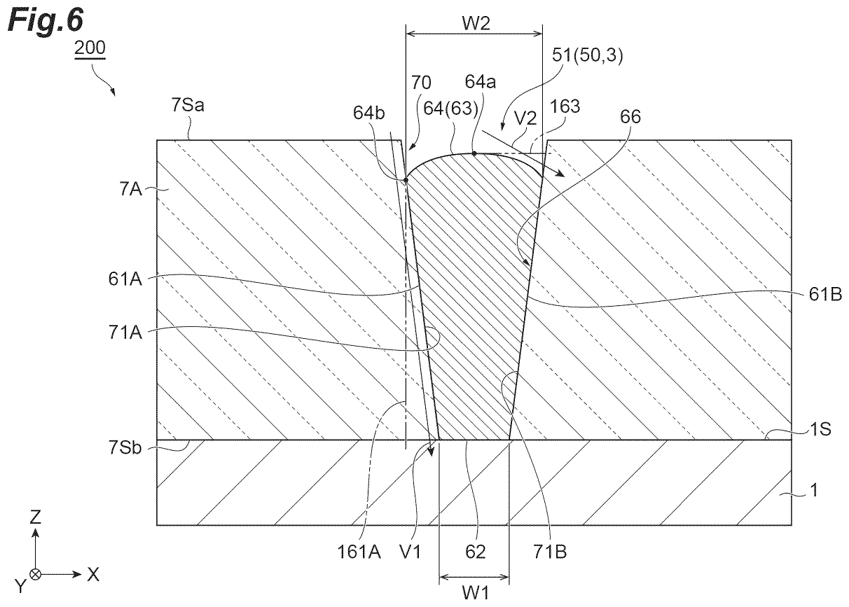

Next, the detailed configuration of the conductor pattern 50 will be described with reference to FIG. 6. FIG. 6 is a cross-sectional view taken along the line VI-VI in FIG. 5. As illustrated in FIG. 6, the wiring body 200 includes the light transmissive substrate 1, the conductor pattern 50, and the insulating resin portion 7A. The conductor pattern 50 includes the electroconductive lines 51 and 52 extending in the extending direction on the light transmissive substrate 1 (see FIG. 5). Here, the extending direction for the first electroconductive line 51 corresponds to the Y-axis direction. The extending direction for the second electroconductive line 52 corresponds to the X-axis direction. Since the first electroconductive line 51 is illustrated in FIG. 6, the Y-axis direction corresponds to the extending direction. Therefore, the orthogonal direction orthogonal to the extending direction corresponds to the X-axis direction. The height direction corresponds to the Z-axis 25 direction. One side away from the light transmissive substrate 1 in the height direction corresponds to the positive side in the Z-axis direction. The other side which is the light transmissive substrate 1 side in the height direction corresponds to the negative side in the Z-axis direction. FIG. 6 illustrates a cross-sectional view of the first electroconductive line 51 when cut in the X-axis direction that is the orthogonal direction. Although FIG. 6 illustrates the configuration of the first electroconductive line 51, the second electroconductive line 52 also has the same structure, and thus description thereof is omitted.

The first electroconductive line 51 has side surfaces 61A and 61B facing each other in the X-axis direction that is the width direction. The side surface 61A is located on the negative side in the X-axis direction, and the side surface 61B is located on the positive side in the X-axis direction. The first electroconductive line 51 has a bottom surface 62 on the other side in the height direction (negative side in the Z-axis direction). The bottom surface 62 is in surface contact with the main surface 1S of the light transmissive substrate 1. The first electroconductive line 51 has a surface 63 on one side in the height direction (positive side in the Z-axis direction).

The insulating resin portion 7A has a trench 70 in which the first electroconductive line 51 is disposed. In the present embodiment, the trench 70 extends from a surface 7Sa on one side (positive side in the Z-axis direction) in the height direction of the insulating resin portion 7A to a bottom surface 7Sb on the other side (negative side in the Z-axis direction) of the light transmissive substrate 1. The side surfaces 61A and 61B of the first electroconductive line 51 are in surface contact with inner surfaces 71A and 71B of the trench 70, respectively.

A width (dimension in the X-axis direction) of the first electroconductive line 51 increases toward one side in the height direction (positive side in the Z-axis direction). That is, the width dimension W2 in the surface 63 of the first electroconductive line 51 is greater than the width dimension W1 in the bottom surface 62 thereof. The side surfaces 61A and 61B each have a taper 66 inclined such that a separation distance between the side surfaces 61A and 61B in the X-axis direction increases toward one side in the height direction (positive side in the Z-axis direction). The width of the electroconductive line in the first electroconductive line 51 having the taper 66 is defined by the maximum dimension of the width of the electroconductive line. A thickness (dimension in the height direction) of the first electroconductive line 51 and the insulating resin portion 7A may be 1.5 to 5.0 μm. In the present embodiment, the thickness (dimension in the height direction) of the first electroconductive line 51 is greater than the width (dimension in the X-axis direction) thereof. That is, an aspect ratio (thickness/width) of the first electroconductive line 51 is set to be greater than 1. The aspect ratio may be 2 or more. The width dimension W2 on the surface 63 of the first electroconductive line 51 may be 110 to 200% greater than the width dimension W1 on the bottom surface 62 thereof.

The surface 63 of the first electroconductive line 51 on a side opposite to the light transmissive substrate 1 is formed with a curved surface 64 that curves so as to protrude to one side in the height direction (positive side in the Z-axis direction) of the first electroconductive line 51. A part of the curved surface 64 of the first electroconductive line 51 that protrudes most toward one side in the height direction (positive side in the Z-axis direction) is defined as an apex 64a. The lowest part of the curved surface 64 is an outer edge portion 64b. In the present embodiment, the apex 64a of the curved surface 64 is disposed at a position lower than the height of the surface 7Sa of the insulating resin portion 7A. As a result, the entire portion including the edge of the curved surface 64 is disposed at a height of the surface 7Sa or less.

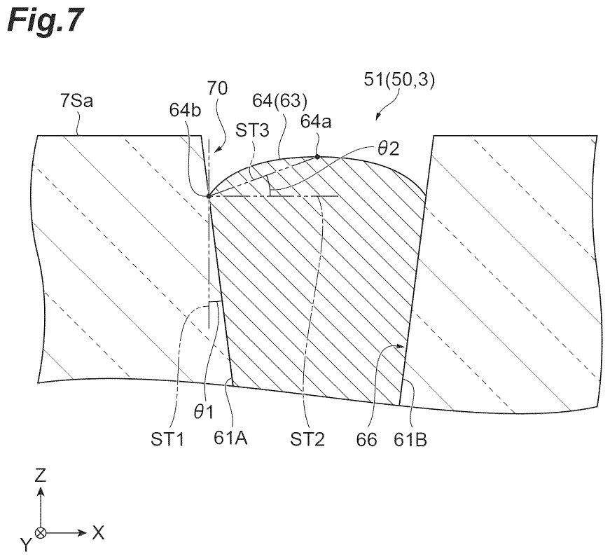

FIG. 7 is an enlarged view of the vicinity of the curved surface 64. An inclination angle of the taper 66 and an inclination angle of the curved surface 64 will be described with reference to FIG. 7. In the cross-sectional view, a reference line ST1 extending in the height direction with respect to the taper 66 is set. An angle formed by the reference line ST1 and the taper 66 is an inclination angle θ1 of the taper 66. A reference line ST2 that passes through the outer edge portion 64b of the curved surface 64 and extends in the X-axis direction is set. A reference line ST3 passing through the outer edge portion 64b and the apex 64a is set. An angle formed by the reference line ST2 and the reference line ST3 is an inclination angle θ2 of the curved surface 64. In a cross-sectional view of the first electroconductive line 51, the inclination angle θ2 of the curved surface 64 of the first electroconductive line 51 may be greater than the inclination angle θ1 of the taper 66 of each of the side surfaces 61A and 61B of the first electroconductive line 51. Note that the inclination angle θ1 of the taper 66 on the side surface 61A of the first electroconductive line 51 and the inclination angle θ1 of the taper 66 on the side surface 61B of the first electroconductive line 51 may be different angles.

Next, functions and effects of the wiring body 200 and the display device 100 according to the present embodiment will be described.

The wiring body 200 according to the present embodiment includes the light transmissive substrate 1 (substrate) and the conductor pattern 50 that is provided on the light transmissive substrate 1 and has the electroconductive lines 51 and 52 extending on the light transmissive substrate 1 in an extending direction, and in a cross-sectional view of the electroconductive lines 51 and 52 taken along a direction orthogonal to the extending direction, the widths of the electroconductive lines 51 and 52 increase toward one side away from the light transmissive substrate 1 in the height direction, and the surface 63 of each of the electroconductive lines 51 and 52 on a side opposite to the light transmissive substrate 1 is formed with the curved surface 64 that curves so as to protrude to one side in the height direction of the electroconductive lines 51 and 52.

According to the wiring body 200, in the cross-sectional view of the electroconductive lines 51 and 52, the widths of the electroconductive lines 51 and 52 increase toward one side away from the light transmissive substrate 1 in the height direction. This configuration can increase the volume of the electroconductive lines 51 and 52 while making the electroconductive lines 51 and 52 less visible from the outside. For example, as illustrated in FIG. 6, a configuration is exemplified in which a side surface 161A (indicated by an imaginary line) according to a comparative example extends straight in the height direction with the width dimension W2 on the surface 63 side unchanged. In such a configuration, a line of sight V1 entering the insulating resin portion 7A without being blocked by the surface 63 is blocked by the side surface 161A on the bottom surface 62 side. In contrast, according to the present embodiment, since the side surface 61A has the taper 66, it is possible to prevent the line of sight V1 from being blocked by the side surface 61A. On the other hand, the width dimension W2 is maintained wide on the surface 63 side, which increases the volume of the electroconductive lines 51 and 52.

Further, in the cross-sectional view of the electroconductive lines 51 and 52, the surface 63 of each of the electroconductive lines 51 and 52 on a side opposite to the light transmissive substrate 1 is formed with the curved surface 64 that curves so as to protrude to one side in the height direction of the electroconductive lines 51 and 52. This configuration can increase the volume of the electroconductive lines 51 and 52 while making the electroconductive lines 51 and 52 less visible from the outside. For example, as illustrated in FIG. 6, a configuration is exemplified in which a surface 163 according to a comparative example extends straight from the apex 64a in the X-axis direction. In such a configuration, a line of sight V2 entering at a large incident angle is blocked by the surface 163. In contrast, according to the present embodiment, the curved surface 64 is formed on the surface 63, which prevents the line of sight V2 from being blocked by the surface 63. On the other hand, in the surface 63, the volume of the electroconductive lines 51 and 52 can be increased by an amount corresponding to a protrusion of the curved surface 64 to one side in the height direction from the outer edge portion 64b. As described above, the sheet resistance of the wiring body 200 can be reduced by increasing the volume of the electroconductive lines 51 and 52 while preventing an increase in visibility of the conductor pattern 50.

In the cross-sectional view of the electroconductive lines 51 and 52, the inclination angle θ2 of the curved surface 64 of each of the electroconductive lines 51 and 52 may be greater than the inclination angle θ1 of the taper 66 of each of the side surfaces 61A and 61B of the electroconductive lines 51 and 52. In such a case, the curvature of the curved surface 64 can be increased, which prevents an increase in visibility with respect to an oblique line of sight such as the line of sight V2 (see FIG. 6).

The wiring body 200 may further include the insulating resin portion 7A provided on the light transmissive substrate 1, and the insulating resin portion 7A may have the trenches 70 in which the electroconductive lines 51 and 52 are disposed. In this case, peeling of the electroconductive lines 51 and 52 from the light transmissive substrate 1 can be prevented.

Note that the edges of the curved surfaces 64 of the electroconductive lines 51 and 52 may be disposed at a height equal to or less than the height of the surface 7Sa of the insulating resin portion 7A. In this case, unevenness is formed between the electroconductive lines 51 and 52 and the insulating resin portion 7A, and the adhesion at the time of bonding the wiring body 200 is increased.

The display device 100 according to an aspect of the present disclosure includes the wiring body 200.

According to the display device 100, functions and effects similar to those of the wiring body 200 described above can be achieved.

The present disclosure is not limited to the embodiment described above.

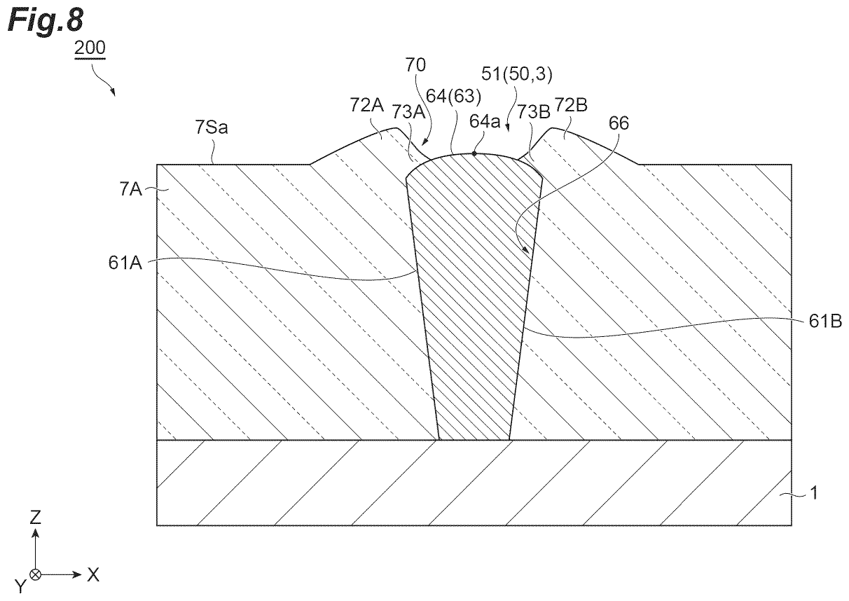

For example, a modification as illustrated in FIG. 8 may be adopted. FIG. 8 is an enlarged cross-sectional view illustrating a wiring body 200 according to a modification. As illustrated in FIG. 8, the insulating resin portion 7A has raised portions 72A and 72B protruding from both sides of the trench 70 to one side (positive side in the Z-axis direction) in the height direction from a surface 7S of the insulating resin portion 7A. The raised portions 72A and 72B are parts where a part of the insulating resin portion 7A is raised. In the vicinity of corners between the side surfaces 61A and 61B and the surface 63, the raised portions 72A and 72B are higher on one side in the height direction than the surface 7Sa of the insulating resin portion 7A. In the curved surface 64 of each of the electroconductive lines 51 and 52, the height of the apex 64a that protrudes most toward one side in the height direction may be equal to or greater than the height of the surface 7Sa of the insulating resin portion 7A and equal to or less than the heights of the raised portions 72A and 72B. In the meantime, the height of the raised portion 72A and the height of the raised portion 72B may be the same as or different from each other. In a case where the height of the raised portion 72A and the height of the raised portion 72B are different from each other, the height of the apex 64a that protrudes most toward one side in the height direction in the curved surface 64 of each of the electroconductive lines 51 and 52 may be equal to or less than the lower of the heights of the raised portions 72A and 72B.

According to such a configuration, the curved surfaces 64 of the electroconductive lines 51 and 52B can protrude beyond the surface 7Sa to increase the cross-sectional area. Further, the raised portions 72A and 72B are provided to form an uneven shape between the electroconductive lines 51 and 52 and the insulating resin portion 7A, which increases the adhesion at the time of bonding the wiring body 200.

The edges of the curved surfaces 64 of the electroconductive lines 51 and 52 may be disposed at a height equal to or less than the height of the surface 7Sa of the insulating resin portion 7A. In this case, unevenness is formed between the electroconductive lines 51 and 52 and the insulating resin portion 7A, and the adhesion at the time of bonding the wiring body 200 is increased.

The insulating resin portion 7A has protrusions 73A and 73B protruding to the trench 70. Further, the protrusions 73A and 73B may cover the edges of the curved surfaces 64 of the electroconductive lines 51 and 52. In this case, peeling of the electroconductive lines 51 and 52 from the light transmissive substrate 1 can be prevented. The insulating resin portion 7A may have only one of the protrusions 73A and 73B. Further, the protrusions 73A and 73B may be in contact with the edges of the curved surfaces 64 of the electroconductive lines 51 and 52. In this case, the effect of preventing peeling of the electroconductive lines 51 and 52 from the light transmissive substrate 1 can be increased.

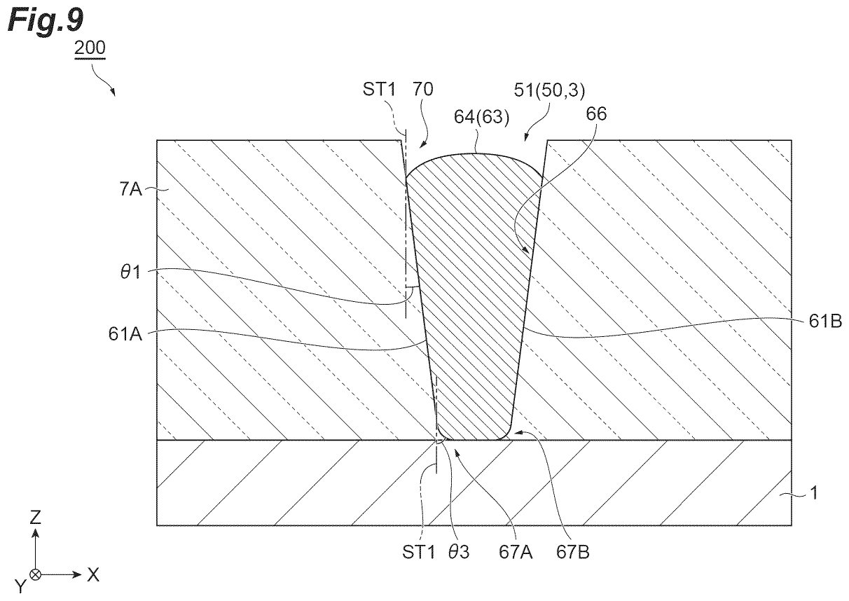

For example, a modification as illustrated in FIG. 9 may be adopted. FIG. 9 is an enlarged cross-sectional view illustrating a wiring body 200 according to a modification. As illustrated in FIG. 9, in a cross-sectional view of the electroconductive lines 51 and 52, the tapers 66 of the side surfaces 61A and 61B of the electroconductive lines 51 and 52 may have portions 67A and 67B having a large change in inclination angle on the light transmissive substrate 1 side. In the portions 67A and 67B, the width dimension of the electroconductive line 51 is sharply reduced. As a result, an inclination angle θ3 of the portions 67A and 67B becomes greater than the inclination angle θ1 of the other portion of the taper 66. According to such a configuration, the visibility of the electroconductive lines 51 and 52 near the light transmissive substrate 1 can be further reduced, while the cross-sectional area can be sufficiently left in the other portion. In the present embodiment also, in the cross-sectional view of the electroconductive lines 51 and 52, the inclination angle θ2 of the curved surface 64 of each of the electroconductive lines 51 and 52 may be greater than the inclination angle θ1 of the taper 66 of each of the side surfaces 61A and 61B of the electroconductive lines 51 and 52.

It is not always necessary that the curved surface 64 is formed in the entire region of the surface 63, and the curved surface 64 may be formed in a partial region thereof. In addition, it is not always necessary that the taper 66 is formed on the entire side surfaces 61A and 61B, and the side surfaces 61A and 61B may partly have a shape that is straight in the height direction or a shape that is inclined to the opposite direction (separation distance decreases).

### [Aspect 1]

A wiring body including: a substrate; and
a conductor pattern provided on the substrate and including an electroconductive line, the electroconductive line extending on the substrate in an extending direction, in which
in a cross-sectional view of the electroconductive line taken along a direction orthogonal to the extending direction,
a width of the electroconductive line increases toward one side away from the substrate in a height direction, and
a curved surface curving so as to protrude to the one side in the height direction is formed on a surface of the electroconductive line on a side opposite to the substrate.

### [Aspect 2]

The wiring body according to aspect 1, in which in the cross-sectional view of the electroconductive line,
an inclination angle of the curved surface of the electroconductive line is greater than an inclination angle of a taper of a side surface in the electroconductive line.

### [Aspect 3]

The wiring body according to aspect 1 or 2, further including a resin layer provided on the substrate, in which the resin layer has a trench in which the electroconductive line is disposed.

### [Aspect 4]

The wiring body according to aspect 3, in which the resin layer includes a raised portion protruding from both sides of the trench toward the one side in the height direction beyond a surface of the resin layer, and
a height of an apex protruding most toward the one side in the height direction in the curved surface of the electroconductive line is equal to or greater than a height of the surface of the resin layer and equal to or less than a height of the raised portion.

### [Aspect 5]

The wiring body according to aspect 3 or 4, in which an edge of the curved surface of the electroconductive line is disposed at a height equal to or less than a height of a surface of the resin layer.

### [Aspect 6]

The wiring body according to any one of aspects 3 to 5, in which the resin layer includes a protrusion protruding into the trench, and the protrusion covers an edge of the curved surface of the electroconductive line.

### [Aspect 7]

The wiring body according to any one of aspects 1 to 6, in which in the cross-sectional view of the electroconductive line,
a taper of a side surface of the electroconductive line has a part having a large change in an inclination angle on the substrate side as compared to another part.

### [Aspect 8]

A display device including the wiring body according to any one of aspects 1 to 7.

### REFERENCE SIGNS LIST

1 Light transmissive substrate (substrate)
1S Main surface of substrate
7A Insulating resin portion (resin layer)
50 Conductor pattern
51, 52 Electroconductive line
61A, 61B Side surface
63 Surface
64 Curved surface
64a Apex
66 Taper
70 Trench
72A, 72B Raised portion
73A, 73B Protrusion
100 Display device
200 Wiring body

What is claimed is:

1. A wiring body comprising: a substrate; and
a conductor pattern provided on the substrate and including an electroconductive line, the electroconductive line extending on the substrate in an extending direction, wherein
in a cross-sectional view of the electroconductive line taken along a direction orthogonal to the extending direction,
a width of the electroconductive line increases toward one side away from the substrate in a height direction, and
a curved surface curving so as to protrude to the one side in the height direction is formed on a surface of the electroconductive line on a side opposite to the substrate.

2. The wiring body according to claim 1, wherein in the cross-sectional view of the electroconductive line,
an inclination angle of the curved surface of the electroconductive line is greater than an inclination angle of a taper of a side surface in the electroconductive line.

3. The wiring body according to claim 1, further comprising a resin layer provided on the substrate, wherein
the resin layer has a trench in which the electroconductive line is disposed.

4. The wiring body according to claim 3, wherein the resin layer includes a raised portion protruding from both sides of the trench toward the one side in the height direction beyond a surface of the resin layer, and
a height of an apex protruding most toward the one side in the height direction in the curved surface of the electroconductive line is equal to or greater than a height of the surface of the resin layer and equal to or less than a height of the raised portion.

5. The wiring body according to claim 3, wherein an edge of the curved surface of the electroconductive line is disposed at a height equal to or less than a height of a surface of the resin layer.

6. The wiring body according to claim 3, wherein the resin layer includes a protrusion protruding into the trench, and the protrusion covers an edge of the curved surface of the electroconductive line.

7. The wiring body according to claim 1, wherein in the cross-sectional view of the electroconductive line,
a taper of a side surface of the electroconductive line has a part having a large change in an inclination angle on the substrate side as compared to another part.

8. A display device including the wiring body according to claim 1.
